(19) United States
(12) Patent Application Publication
(10) Pub. No.: US 2024/0030223 A1
(43) Pub. Date: Jan. 25, 2024

(54) DISPLAY PANEL AND ELECTRONIC DISPLAY DEVICE

(71) Applicant: TCL China Star Optoelectronics Technology Co., Ltd., Shenzhen, Guangdong (CN)

(72) Inventors: Macai LU, Shenzhen, Guangdong (CN); Nian LIU, Shenzhen, Guangdong (CN)

(73) Assignee: TCL China Star Optoelectronics Technology Co., Ltd., Shenzhen, Guangdong (CN)

(21) Appl. No.: 17/607,446

(22) PCT Filed: Sep. 26, 2021
(86) PCT No.: PCT/CN2021/120760

§ 371 Date: Oct. 29, 2021

(30) Foreign Application Priority Data
Sep. 22, 2021 (CN) 202111107179.7

(51) Int. Cl. H01L 27/12; H01L 25/16

(52) U.S. Cl. CPC H01L 27/1222; H01L 25/167; H01L 27/124

(57) ABSTRACT

The present invention relates to a display panel and an electronic display device. A first source of a driving thin film transistor extends and covers a first gate layer, the first source is used to block water vapor, thus to prevent water vapor intrusion from reducing weather resistance of the driving thin film transistor, to improve a service life of the driving thin film transistor, and to prevent a degradation or a failure of display qualities caused by a decline during use of the driving thin film transistor, and to improve display stability of the display panel.

### BACKGROUND OF INVENTION

### Field of Invention

The present application relates to a field of display technology, and particularly to a display panel and an electronic display device.

### Description of Prior Art

At present, as current driven displays, driving thin film transistors (TFT) of organic light-emitting diodes (OLEDs), micro light-emitting diodes (micro LEDs), and submillimeter light-emitting diodes (mini LEDs) require a large current carrying capacity, a good device stability, a good in-plane threshold voltage (Vth) uniformity, and low leakage current.

Top gate self-aligned oxide semiconductor thin film transistors have characteristics of high mobility, small parasitic capacitance, and low leakage current, which is more suitable for current driven display circuits. In order to prevent a decline of TFT during use, resulting in a degradation or a failure of display quality, active-matrix (AM) micro LEDs and AM mini LEDs also need driving substrates with high weather resistance. Since a top of channels of the top gate thin film transistors is provided with a gate insulating (GI) layer and a gate layer as a protective layer, its weather resistance is better than a back channel etch (BCE) structure and an etch stop layer (ESL) structure.

### SUMMARY OF INVENTION

In current top gate thin film transistors, a top surface of gate layers is not covered by metal films, so it leads to infiltration of water and gas in a working process, which affects characteristics of TFT devices, resulting in an inability to achieve optimal weather resistance.

An object of the present invention is to provide a display panel and an electronic display device, which can solve a problem of affecting the weather resistance of TFT due to water and gas penetration in the current top gate thin film transistors.

In order to solve the above problem, the present invention provides a display panel, which comprises a substrate and a plurality of pixel units arranged in an array; each of the pixel units comprising: a buffer layer arranged on the substrate; a driving thin film transistor arranged on a surface of one side of the buffer layer away from the substrate; and a switching thin film transistor arranged on a same layer with the driving thin film transistor and electrically connected to the driving thin film transistor; wherein the driving thin film transistor comprises: a first active layer arranged on the surface of the side of the buffer layer away from the substrate; a first gate insulating layer arranged on a surface of one side of the first active layer away from the substrate; a first gate layer arranged on a surface of one side of the first gate insulating layer away from the substrate; an interlayer insulating layer covering a surface of one side of the first gate layer away from the substrate and extending and covering the surface of one side of the buffer layer away from the substrate; and a first source/drain layer arranged on a surface of one side of the interlayer insulating layer away from the substrate; wherein the first source/drain layer comprises a first source and a first drain spaced from each other, and the first source extends towards the first drain and covers the first gate layer.

Further, a projection of the first source on the substrate has a first side close to the first drain; a projection of the first gate layer on the substrate has a second side close to the first drain; a projection of the first drain on the substrate has a third side close to the first source; wherein the first side, the second side, and the third side are parallel to each other, and the first side is located between the second side and the third side.

Further, a distance between the first side and the second side ranges from 0.5 μm to 10 μm.

Further, the switching thin film transistor comprises: a second active layer arranged on a same layer with the first active layer and spaced from the first active layer; a second gate insulating layer arranged on a same layer with the first gate insulating layer and spaced from the first gate insulating layer; a second gate layer arranged on a same layer with the first gate layer and spaced from the first gate layer; wherein the interlayer insulating layer extends and covers a surface of one side of the second gate layer away from the substrate; and a second source/drain layer arranged on a same layer with the first source/drain layer and spaced from the first source/drain layer; wherein the second source/drain layer comprises a second source and a second drain spaced from each other.

Further, each of the pixel units further comprises: a scanning wiring unit arranged on a same layer with the second source/drain layer and arranged at intervals with the second source and the second drain respectively, wherein the scanning wiring unit is electrically connected to the second gate layer and arranged corresponding to the second gate layer.

Further, a projection of the scanning wiring unit on the substrate has a fourth side close to the second drain; a projection of the second gate layer on the substrate has a fifth side close to the second drain; a projection of the second drain on the substrate has a sixth side close to the second source; wherein the fourth side, the fifth side, and the sixth side are parallel to each other, and the fourth side is located between the fifth side and the sixth side.

Further, a distance between the fourth side and the fifth side ranges from 0.5 μm to 10 μm.

Further, a high-voltage access source arranged between the substrate and the buffer layer and electrically connected to the driving thin film transistor; a low-voltage access source arranged on a same layer with the high-voltage access source and spaced from the high-voltage access source, wherein the low-voltage access source is electrically connected to the driving thin film transistor; and a data wiring unit arranged on a same layer with the high-voltage access source and spaced from the high-voltage access source, wherein the data wiring unit is electrically connected to the switching thin film transistor.

Further, each of the pixel units further comprises a first capacitor and an induction thin film transistor; wherein the first gate layer is electrically connected to the second drain and the first capacitor, the first source is electrically connected to the low-voltage access source, and the first drain is electrically connected to the high-voltage access source; wherein the second gate layer is electrically connected to the scanning wiring unit, the second source is electrically connected to the data wiring unit, and the second drain is electrically connected to the first capacitor; and the induction thin film transistor comprises a third source electrically connected to the first capacitor.

In order to solve the above problem, the present invention provides an electronic display device, which comprises the display panel of the present invention mentioned above.

The present invention arranges the first source of the driving thin film transistor to extend and over the first gate layer. Using the first source to block water vapor can prevent weather resistance of the driving thin film transistor from being reduced due to the water vapor intrusion, improve a service life of the driving thin film transistor, prevent a degradation or a failure of display qualities caused by a decline during use of the driving thin film transistor, and improve display stability of the display panel. The first source is used as a top shading layer to prevent light from entering the first active layer. By arranging the scanning wiring unit on the second gate layer of the switching thin film transistor, a distance between the scanning wiring unit and the data wiring unit is increased, a short circuit between the scanning wiring unit and the data wiring unit is prevented, and capacitance generated by coupling between the scanning wiring unit and the data wiring unit is reduced. By covering the second gate layer with the scanning wiring unit, water vapor intrusion is prevented and stability of the switching thin film transistor is improved.

### BRIEF DESCRIPTION OF DRAWINGS

In order to explain embodiments or technical solutions in prior arts clearly, the following will briefly introduce drawings needed to be used in description of the embodiments or the prior arts. It is obvious that the drawings in the following description are only some embodiments of the invention. For those skilled in the art, other drawings can also be obtained from these drawings without paying creative labor.

FIG. 1 is a plane schematic diagram of a display panel of the present invention.

FIG. 2 is a schematic structural diagram of a pixel unit of the display panel of the present invention.

FIG. 3 is a partial plane schematic diagram of the pixel unit of the display panel of the present invention.

FIG. 4 is a circuit schematic diagram of the pixel unit of the display panel of the present invention.

FIG. 5 is a schematic structural diagram of forming a first light-shielding layer, a high-voltage access source, a low-voltage access source, a data wiring unit, and a buffer layer on a substrate.

FIG. 6 is a schematic structural diagram of forming a first active layer and a second active layer on a basis of FIG. 5.

FIG. 7 is a schematic structural diagram of forming a first gate insulating layer, a second gate insulating layer, a first gate layer, and a second gate layer on a basis of FIG. 6.

FIG. 8 is a schematic structural diagram of forming an interlayer insulating layer based on FIG. 7.

FIG. 9 is a schematic structural diagram of forming a first source/drain layer, a second source/drain layer, and a scanning wiring unit on a basis of FIG. 8.

FIG. 10 is a schematic structural diagram of forming a passivation layer on a basis of FIG. 9.

FIG. 11 is a schematic structural diagram of forming a first electrode and a second electrode on a basis of FIG. 10.

FIG. 12 is a schematic diagram of a mobility change of the display panel of the present invention under a high temperature and a high humidity storage test.

FIG. 13 is a schematic diagram of a threshold voltage change of the display panel of the present invention under the high temperature and the high humidity storage test.

### DESCRIPTION OF REFERENCE MARKS

100. A display panel; 101. A pixel unit;
1011. A driving thin film transistor; 1012. A switching thin film transistor;
1013. A light-emitting diode;
1. A substrate; 2. A first light-shielding layer;
3. A high-voltage access source; 4. A low-voltage access source;
5. A buffer layer; 6. A first active layer;
7. A first gate insulating layer; 8. A first gate layer;
9. A first source/drain layer; 10. An interlayer insulation layer;
11. A passivation layer; 12. A data wiring unit;
13. A second active layer; 14. A second gate insulating layer;
15. A second gate layer; 16. A second source/drain layer;
17. A scanning wiring unit; 18. A first electrode;
19. A second electrode;
91. A first source; 92. A first drain;
161. A second source; 162. A second drain;
911, A first side; 81. A second side;
921. A third side.

### DETAILED DESCRIPTION OF EMBODIMENTS

Preferred embodiments of the present invention is described in detail below in combination with accompanying drawings of the description, so as to fully introduce a technical content of the present invention to those skilled in the art, so as to prove that the present invention can be implemented, make the technical content disclosed by the present invention clearer, and make it easier for those skilled in the art to understand how to implement the present invention. However, the present invention can be embodied in many different forms of embodiments. A protection scope of the present invention is not limited to the embodiments mentioned herein, and descriptions of the embodiments below is not used to limit the scope of the present invention.

Directional terms mentioned in the present invention, such as “up”, “down”, “front”, “back”, “left”, “right”, “inside”, “outside”, “side”, etc., are only directions in the drawings. The directional terms used in this paper are used to explain and explain the present invention, not to limit the protection scope of the present invention.

In the drawings, components with a same structure are represented by same number, and components with a similar structure or a function are represented by a same number. In addition, for ease of understanding and description, a size and a thickness of each component shown in the drawings are arbitrarily shown, and the present invention does not limit the size and the thickness of each component.

The present invention provides an electronic display device, which comprises a display panel 100. The electronic display device comprises a mobile phone, a computer, an MP3, an MP4, a tablet computer, a TV, or a digital camera, etc.

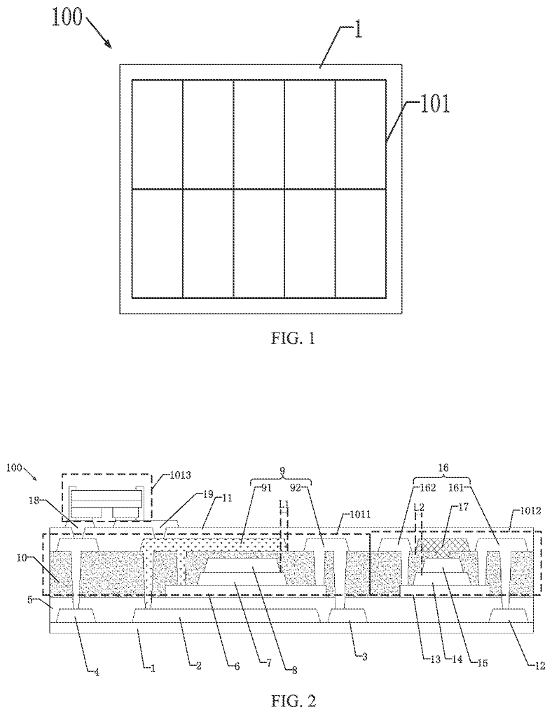

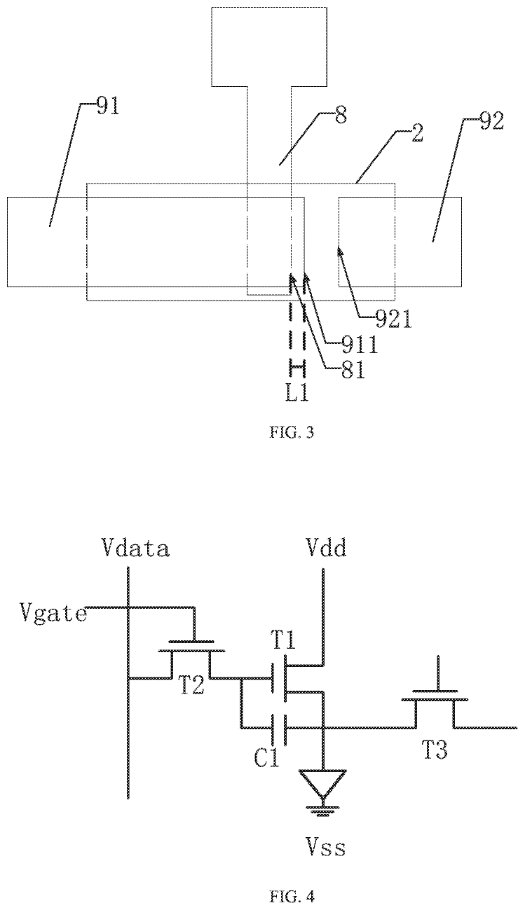

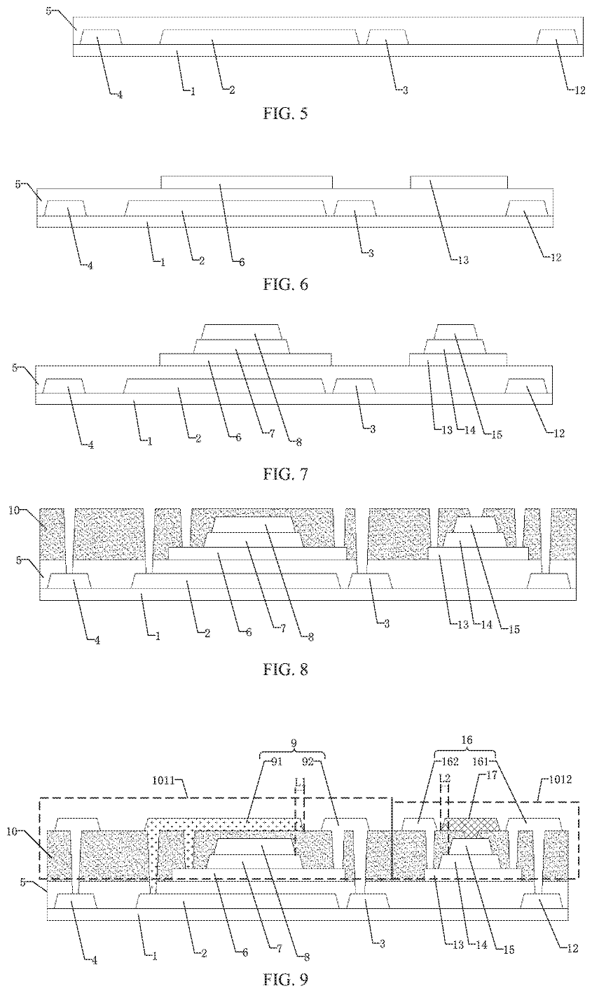

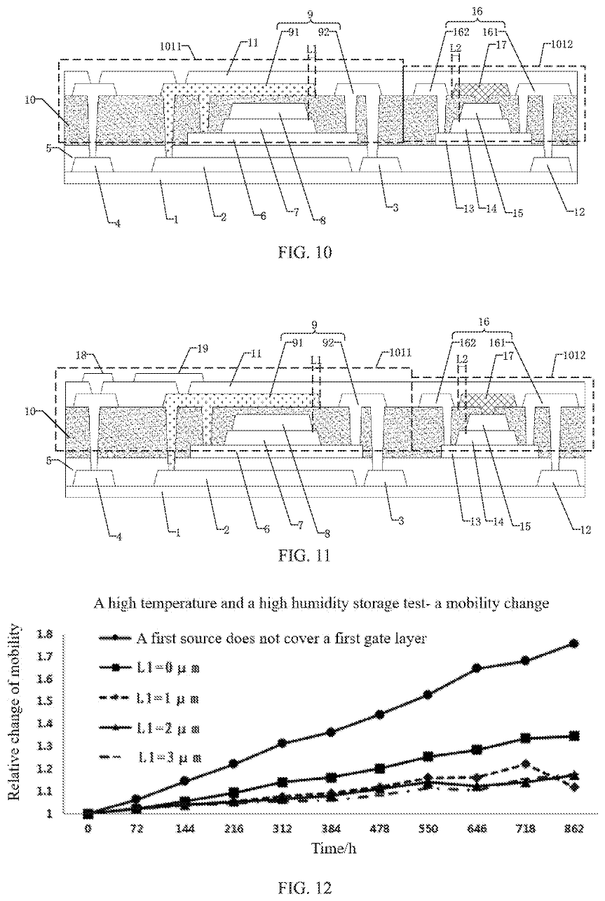

As shown in FIG. 1, the display panel 100 comprises a substrate 1 and a plurality of pixel units 101 arranged in an array on the substrate 1.

Wherein, materials of the substrate 1 comprise polyimide, polycarbonate, polyethylene terephthalate, and polyethylene naphthalate. Thus, the substrate 1 has good impact resistance and can effectively protect the display panel 100.

As shown in FIG. 2, each of the pixel units 101 comprises a first light-shielding layer 2, a high-voltage access source 3, a low-voltage access source 4, a buffer layer 5, a driving thin film transistor 1011, and a switching thin film transistor 1012.

Wherein, the first light-shielding layer 2 is arranged on a surface of one side of the substrate 1, and the first light-shielding layer 2 is mainly used to prevent light from entering a first active layer 6 of a driving thin film transistor 1011. Wherein materials of the first light-shielding layer 2 can be Mo, a combined structure of Mo and Al, a combined structure of Mo and Cu, a combined structure of Mo, Cu and IZO, a combined structure of IZO, Cu and IZO, a combined structure of Mo, Cu and ITO, a combined structure of Ni, Cu and Ni, a combined structure of MoTiNi, Cu and MoTiNi, a combined structure of NiCr, Cu and NiCr, or CuNb, etc.

Wherein, the high-voltage access source 3 is arranged on a surface of one side of the first substrate 1 and on a same layer with the first light-shielding layer 2; in addition, the high-voltage access source 3 is spaced from the first light-shielding layer 2 and electrically connected to the driving thin film transistor 1011. Wherein materials of the high-voltage access source 3 can be Mo, the combined structure of Mo and Al, the combined structure of Mo and Cu, the combined structure of Mo, Cu and IZO, the combined structure of IZO, Cu and IZO, the combined structure of Mo, Cu and ITO, the combined structure of Ni, Cu and Ni, the combined structure of MoTiNi, Cu and MoTiNi, the combined structure of NiCr, Cu and NiCr, or CuNb, etc.

Wherein, the low-voltage access source 4 is arranged on a surface of one side of the first substrate 1 and on a same layer with the high-voltage access source 3; in addition, the low-voltage access source 4 is spaced from the first light-shielding layer 2 and the high-voltage access source 3 and electrically connected to the driving thin film transistor 1011. That is, the first light-shielding layer 2, the high-voltage access source 3, and the low-voltage access source 4 are arranged on a same layer, and the above three layers are arranged at intervals from each other. Wherein materials of the low-voltage access source 4 can be Mo, the combined structure of Mo and Al, the combined structure of Mo and Cu, the combined structure of Mo, Cu and IZO, the combined structure of IZO, Cu and IZO, the combined structure of Mo, Cu and ITO, the combined structure of Ni, Cu and Ni, the combined structure of MoTiNi, Cu and MoTiNi, the combined structure of NiCr, Cu and NiCr, or CuNb, etc.

Wherein, the buffer layer 5 covers the first light-shielding layer 2, the high-voltage access source 3, and the low-voltage access source 4; in addition, the buffer layer 5 also extends and overs the substrate 1 between the first light-shielding layer 2, the high-voltage access source 3, and the low-voltage access source 4. Wherein, the buffer layer 5 mainly plays a buffer role, and its materials can be SiOₓ, SiNₓ, SiNOₓ, or a combined structure of SiNₓ and SiOₓ.

Wherein, the driving thin film transistor 1011 is arranged on a surface of one side of the buffer layer 5 away from the substrate 1. The driving thin film transistor comprises the first active layer 6, a first gate insulating layer 7, a first gate layer 8, an interlayer insulating layer 10, and a first source/drain layer 9.

Wherein, the first active layer 6 is arranged on the surface of one side of the buffer layer 5 away from the substrate 1. The first active layer 6 can be an oxide semiconductor or other types of semiconductors, such as IGZO, IGTO, IGO, IZO, and AIZO, etc.

Wherein, the first gate insulating layer 7 is arranged on a surface of one side of the first active layer 6 away from the substrate 1. The first gate insulating layer 7 is mainly used to prevent a short circuit arising from contact between the first active layer 6 and the first gate layer 8. Materials of the first gate insulating layer 7 can be SiOₓ, SiNₓ, Al₂O₃, the combined structure of SiNₓ and SiOₓ, or a combined structure of SiOₓ, SiNₓ and SiNOₓ.

Wherein, the first gate layer 8 is arranged on a surface of one side of the first gate insulating layer 7 away from the substrate 1. Materials of the first gate layer 8 can be Mo, the combined structure of Mo and Al, the combined structure of Mo and Cu, the combined structure of Mo, Cu and IZO, the combined structure of IZO, Cu and IZO, the combined structure of Mo, Cu and ITO, the combined structure of Ni, Cu and Ni, the combined structure of MoTiNi, Cu and MoTiNi, the combined structure of NiCr, Cu and NiCr, or CuNb, etc.

Wherein, the interlayer insulating layer 10 covers a surface of one side of the first gate layer 8 on one side away from the substrate 1, and extends and covers a surface of the buffer layer 5 on one side away from the substrate 1. Wherein materials of the interlayer insulating layer 10 can be SiOₓ, SiNₓ, or SiNOₓ.

Wherein, the first source/drain layer 9 is arranged on a surface of one side of the interlayer insulating layer 10 away from the substrate 1. Materials of the first source/drain layer 9 can be Mo, the combined structure of Mo and Al, the combined structure of Mo and Cu, the combined structure of Mo, Cu and IZO, the combined structure of IZO, Cu and IZO, the combined structure of Mo, Cu and ITO, the combined structure of Ni, Cu and Ni, the combined structure of MoTiNi, Cu and MoTiNi, the combined structure of NiCr, Cu and NiCr, or CuNb, etc.

As shown in FIG. 2, the first source/drain layer 9 comprises a first source 91 and a first drain 92 spaced from each other.

As shown in FIG. 2 and FIG. 3, the first source 91 extends towards the first drain and covers the first gate layer 8.

As shown in FIGS. 2 and 3, a projection of the first source 91 on the substrate 1 has a first side 911 close to the first drain 92; a projection of the first gate layer 8 on the substrate 1 has a second side 81 close to the first drain 92; and a projection of the first drain 92 on the substrate 1 has a third side 921 close to the first source 91; wherein the first side 911, the second side 81, and the third side 921 are parallel to each other, and the first side 911 is located between the second side 81 and the third side 921. Wherein, a distance L1 between the first side 911 and the second side 81 ranges from 0.5 μm to 10 μm.

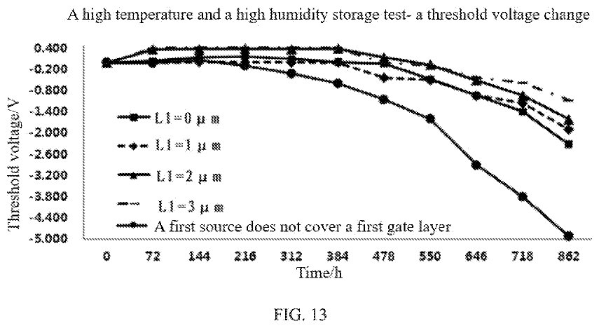

As shown in FIG. 12 and FIG. 13, when the distance L1=2 μm, a change curve of mobility and a threshold voltage tends to be stable, so in the embodiment, the distance L1 is preferably 2 μm.

Using the first source 91 to block water vapor can prevent weather resistance of the driving thin film transistor 1011 from being reduced due to the water vapor intrusion, improve a service life of the driving thin film transistor 1011, prevent a degradation or a failure of display qualities caused by a decline during use of the driving thin film transistor 1011, and improve display stability of the display panel 100. The first source 91 is used as a top shading layer to prevent light from entering the first active layer 6.

As shown in FIG. 2, the switching thin film transistor 1012 is arranged on a same layer with the driving thin film transistor 1011 and electrically connected to the driving thin film transistor 1011. The switching thin film transistor 1012 comprises a second active layer 13, a second gate insulating layer 14, a second gate layer 15, and a second source/drain layer 16. Wherein, the second active layer 13 is arranged on the surface of the side of the buffer layer 5 away from the substrate 1, and the second active layer 13 is arranged on a same layer with the first active layer 6 and spaced from the first active layer 6. The second active layer 13 can be an oxide semiconductor or other types of semiconductors, such as IGZO, IGTO, IGO, IZO, and AIZO, etc.

Wherein, the second gate insulating layer 14 is arranged on a surface of one side of the second active layer 13 away from the substrate 1, and the second gate insulating layer 14 is arranged on a same layer with the first gate insulating layer 7 and spaced from the first gate insulating layer 7. The second gate insulating layer 14 is mainly used to prevent a short circuit phenomenon arising from contact between the second active layer 13 and the second gate layer 15. Materials of the second gate insulating layer 14 can be SiOₓ, SiNₓ, Al₂O₃, the combined structure of SiNₓ and SiOₓ, or a combined structure of SiOₓ, SiNₓ and SiNOₓ.

Wherein, the second gate layer 15 is arranged on a surface of one side of the second gate insulating layer 14 away from the substrate 1, and the second gate layer 15 is arranged on a same layer with the first gate layer 8 and spaced from the first gate layer 8. Materials of the second gate layer 15 can be Mo, the combined structure of Mo and Al, the combined structure of Mo and Cu, the combined structure of Mo, Cu and IZO, the combined structure of IZO, Cu and IZO, the combined structure of Mo, Cu and ITO, the combined structure of Ni, Cu and Ni, the combined structure of MoTiNi, Cu and MoTiNi, the combined structure of NiCr, Cu and NiCr, or CuNb, etc.

Wherein, the interlayer insulating layer 10 extends and covers a surface of the second gate layer 15 on one side away from the substrate 1.

Wherein, the second source/drain layer 16 is arranged on a surface of one side of the interlayer insulating layer 10 away from the substrate 1, and the second source/drain layer 16 is arranged on a same layer with the first source/drain layer 9 and spaced from the first source/drain layer 9. Materials of the second source/drain layer 16 can be Mo, the combined structure of Mo and Al, the combined structure of Mo and Cu, the combined structure of Mo, Cu and IZO, the combined structure of IZO, Cu and IZO, the combined structure of Mo, Cu and ITO, the combined structure of Ni, Cu and Ni, the combined structure of MoTiNi, Cu and MoTiNi, the combined structure of NiCr, Cu and NiCr, or CuNb, etc.

As shown in FIG. 2, the second source/drain layer 16 comprises a second source 161 and a second drain 162 spaced from each other.

As shown in FIG. 2, each of the pixel units also comprises a passivation layer 11, a data wiring unit 12, and a scanning wiring unit 17.

Wherein, the passivation layer 11 covers the first source/drain layer 9, and extends and covers the interlayer insulating layer 10. Materials of the passivation layer 11 can be SiOₓ, SiNₓ, SiNOₓ, or the combined structure of SiNₓ and SiOₓ.

Wherein, the data wiring unit 12 is arranged on a same layer with the high-voltage access source 3, and the data wiring unit 12 is spaced from the high-voltage access source 3 and electrically connected to the switching thin film transistor 1012. Materials of the data wiring unit 12 can be Mo, the combined structure of Mo and Al, the combined structure of Mo and Cu, the combined structure of Mo, Cu and IZO, the combined structure of IZO, Cu and IZO, the combined structure of Mo, Cu and ITO, the combined structure of Ni, Cu and Ni, the combined structure of MoTiNi, Cu and MoTiNi, the combined structure of NiCr, Cu and NiCr, or CuNb, etc.

Wherein, the scanning wiring unit 17 is arranged on a same layer with the second source/drain layer 16, and the scanning wiring unit 17 is spaced from the second source 161 and the second drain 162, electrically connected to the second gate layer 15, and arranged corresponding to the second gate layer 15.

Wherein, a projection of the scanning wiring unit 17 on the substrate 1 has a fourth side close to the second drain 162; a projection of the second gate layer 15 on the substrate 1 has a fifth side close to the second drain 162; and a projection of the second drain 162 on the substrate 1 has a sixth side close to the second source 161; wherein the fourth side, the fifth side, and the sixth side are parallel to each other, and the fourth side is located between the fifth side and the sixth side. Wherein, a distance L2 between the fourth side and the fifth side ranges from 0.5 μm to 10 μm. In the embodiment, the distance L2 is 2 μm. By arranging the scanning wiring unit 17 on the second gate layer 15 of the switching thin film transistor 1012, a distance between the scanning wiring unit 17 and the data wiring unit 12 is increased, a short circuit between the scanning wiring unit 17 and the data wiring unit 12 is prevented, and capacitance generated by coupling between the scanning wiring unit 17 and the data wiring unit 12 is reduced. By covering the second gate layer 15 with the scanning wiring unit 17, water vapor intrusion is prevented and stability of the switching thin film transistor 1012 is improved.

As shown in FIG. 2, each of the pixel units 101 also comprises a first electrode 18, a second electrode 19, and a light-emitting diode 1013.

Wherein, the first electrode 18 is electrically connected to the low-voltage access source 4; the second electrode 19 is electrically connected to the first source 91; one end of the light-emitting diode 1013 is electrically connected to the first electrode 18, and other end of the light emitting diode 1013 is electrically connected to the second electrode 19.

As shown in FIG. 2 and FIG. 4, each of the pixel units 101 also comprises a first capacitor C1. The first capacitor C1 is formed by coupling the first source 91 with the first gate layer 8. As shown in FIG. 2 and FIG. 4, the first gate layer 8 of the driving thin film transistor 1011 (i.e., T1 in FIG. 4) is electrically connected to the second drain 162 and to a left end of the first capacitor C1; the first source 91 of the driving thin film transistor 1011 (i.e. T1 in FIG. 4) is electrically connected to the low-voltage access source 4 (i.e. Vss in FIG. 4), and the first drain 92 of the driving thin film transistor 1011 (i.e. T1 in FIG. 4) is electrically connected to the high-voltage access source 3 (i.e. Vdd in FIG. 4).

As shown in FIG. 2 and FIG. 4, the second gate layer 15 of the switching thin film transistor 1012 (i.e., T2 in FIG. 4) is electrically connected to the scanning wiring unit 17 (i.e., V gate in FIG. 4), the second source 161 of the switching thin film transistor (i.e., T2 in FIG. 4) is electrically connected to the data wiring unit (i.e., Vdata in FIG. 4), and the second drain 162 of the switching thin film transistor (i.e., T2 in FIG. 4) is electrically connected to the left end of the first capacitor C1.

As shown in FIG. 4, each of the pixel units 101 also comprises an induction thin film transistor T3. The induction thin film transistor T3 comprises a third source. The third source of the induction thin film transistor T3 is electrically connected to a right end of the first capacitor C1.

As shown in FIG. 5-FIG. 11, an embodiment also provides a preparation method of the display panel described in the above embodiment, which specifically comprises following steps.

As shown in FIG. 5, the first light-shielding layer 2, the high-voltage access source 3, the low-voltage access source 4, and the data wiring unit 12 are prepared on the substrate 1. Wherein the first light-shielding layer 2, the high-voltage access source 3, the low-voltage access source 4, and the data wiring unit 12 can be formed synchronously, which can improve production efficiency and save production cost. Then, the buffer layer 5 is prepared on the first light-shielding layer 2, the high-voltage access source 3, the low-voltage access source 4, and the data wiring unit 12.

As shown in FIG. 6, the first active layer 6 and the second active layer 13 are formed on the surface of one side of the buffer layer 5 away from the substrate 1. The first active layer 6 and the second active layer 13 can be formed synchronously, which can improve the production efficiency and save the production cost.

As shown in FIG. 7, the first gate insulating layer 7 is formed on the surface of the side of the first active layer 6 away from the substrate 1, and the second gate insulating layer 14 is formed on the surface of one side of the second active layer 13 away from the substrate 1. The first gate insulating layer 7 and the second gate insulating layer 14 can be formed synchronously, which can improve the production efficiency and save the production cost. Then, the first gate layer 8 is formed on the surface of one side of the first gate insulating layer 7 away from the substrate 1, and the second gate layer 15 is formed on the surface of one side of the second gate insulating layer 14 away from the substrate 1. The first gate layer 8 and the second gate layer 15 can be formed synchronously, which can improve the production efficiency and save the production cost.

As shown in FIG. 8, the interlayer insulating layer 10 is formed on a surface of one side of the first gate layer 8, the second gate layer 15, and the buffer layer 5 away from the substrate 1.

As shown in FIG. 9, the first source/drain layer 9, the second source/drain layer 16, and the scanning wiring unit 17 are formed on the surface of one side of the interlayer insulating layer 10 away from the substrate 1. Wherein the first source/drain layer 9, the second source/drain layer 16, and the scanning wiring unit 17 can be formed synchronously, which can improve the production efficiency and save the production cost.

As shown in FIG. 10, the passivation layer 11 is formed on a surface of one side of the first source/drain layer 9, the second source/drain layer 16, and the scanning wiring unit 17 away from the substrate.

As shown in FIG. 11, the first electrode 18 and the second electrode 19 are formed on a surface of one side of the passivation layer 11 away from the substrate 1.

As shown in FIG. 2, one end of the light-emitting diode 1013 is electrically connected to the first electrode 18, and the other end of the light-emitting diode 1013 is electrically connected to the second electrode 19.

The above describes in detail the display panel and the electronic display device provided by the present application. In this paper, specific examples are applied to explain a principle and an implementation mode of the present application. The description of the above embodiments is only used to help understand a method and core idea of the present application; Meanwhile, for those skilled in the art, there will be changes in specific implementations mode and application scopes according to the idea of the present application. In conclusion, contents of the specifications should not be understood as restrictions on the present application.

What is claimed is:

1. A display panel, comprising a substrate and a plurality of pixel units arranged in an array; each of the pixel units comprising:
a buffer layer arranged on the substrate;
a driving thin film transistor arranged on a surface of one side of the buffer layer away from the substrate; and
a switching thin film transistor arranged on a same layer with the driving thin film transistor and electrically connected to the driving thin film transistor;
wherein the driving thin film transistor comprises:
a first active layer arranged on the surface of the side of the buffer layer away from the substrate;
a first gate insulating layer arranged on a surface of one side of the first active layer away from the substrate;
a first gate layer arranged on a surface of one side of the first gate insulating layer away from the substrate;
an interlayer insulating layer covering a surface of one side of the first gate layer away from the substrate and extending and covering the surface of one side of the buffer layer away from the substrate; and
a first source/drain layer arranged on a surface of one side of the interlayer insulating layer away from the substrate;
wherein the first source/drain layer comprises a first source and a first drain spaced from each other, and the first source extends towards the first drain and covers the first gate layer.

2. The display panel according to claim 1, wherein
a projection of the first source on the substrate has a first side close to the first drain;
a projection of the first gate layer on the substrate has a second side close to the first drain;
a projection of the first drain on the substrate has a third side close to the first source;
wherein the first side, the second side, and the third side are parallel to each other, and the first side is located between the second side and the third side.

3. The display panel according to claim 2, wherein a distance between the first side and the second side ranges from 0.5 μm to 10 μm.

4. The display panel according to claim 1, wherein the switching thin film transistor comprises:
a second active layer arranged on a same layer with the first active layer and spaced from the first active layer;
a second gate insulating layer arranged on a same layer with the first gate insulating layer and spaced from the first gate insulating layer;
a second gate layer arranged on a same layer with the first gate layer and spaced from the first gate layer; wherein the interlayer insulating layer extends and covers a surface of one side of the second gate layer away from the substrate; and
a second source/drain layer arranged on a same layer with the first source/drain layer and spaced from the first source/drain layer; wherein the second source/drain layer comprises a second source and a second drain spaced from each other.

5. The display panel according to claim 4, wherein each of the pixel units further comprises:
a scanning wiring unit arranged on a same layer with the second source/drain layer and arranged at intervals with the second source and the second drain respectively, wherein the scanning wiring unit is electrically connected to the second gate layer and arranged corresponding to the second gate layer.

6. The display panel according to claim 5, wherein
a projection of the scanning wiring unit on the substrate has a fourth side close to the second drain;
a projection of the second gate layer on the substrate has a fifth side close to the second drain;
a projection of the second drain on the substrate has a sixth side close to the second source;
wherein the fourth side, the fifth side, and the sixth side are parallel to each other, and the fourth side is located between the fifth side and the sixth side.

7. The display panel according to claim 6, wherein a distance between the fourth side and the fifth side ranges from 0.5 μm to 10 μm.

8. The display panel according to claim 5, wherein each of the pixel units further comprises:
a high-voltage access source arranged between the substrate and the buffer layer and electrically connected to the driving thin film transistor;
a low-voltage access source arranged on a same layer with the high-voltage access source and spaced from the high-voltage access source, wherein the low-voltage access source is electrically connected to the driving thin film transistor; and
a data wiring unit arranged on a same layer with the high-voltage access source and spaced from the high-voltage access source, wherein the data wiring unit is electrically connected to the switching thin film transistor.

9. The display panel according to claim 8, wherein each of the pixel units further comprises a first capacitor and an induction thin film transistor;
wherein the first gate layer is electrically connected to the second drain and the first capacitor, the first source is electrically connected to the low-voltage access source, and the first drain is electrically connected to the high-voltage access source;
wherein the second gate layer is electrically connected to the scanning wiring unit, the second source is electrically connected to the data wiring unit, and the second drain is electrically connected to the first capacitor; and
the induction thin film transistor comprises a third source electrically connected to the first capacitor.

10. An electronic display device, comprising a display panel; wherein the display panel comprises a substrate and a plurality of pixel units arranged in an array; each of the pixel units comprising:
a buffer layer arranged on the substrate;
a driving thin film transistor arranged on a surface of one side of the buffer layer away from the substrate; and
a switching thin film transistor arranged on a same layer with the driving thin film transistor and electrically connected to the driving thin film transistor;
wherein the driving thin film transistor comprises:
a first active layer arranged on the surface of the side of the buffer layer away from the substrate;
a first gate insulating layer arranged on a surface of one side of the first active layer away from the substrate;
a first gate layer arranged on a surface of one side of the first gate insulating layer away from the substrate;
an interlayer insulating layer covering a surface of one side of the first gate layer away from the substrate and extending and covering the surface of one side of the buffer layer away from the substrate; and
a first source/drain layer arranged on a surface of one side of the interlayer insulating layer away from the substrate;
wherein the first source/drain layer comprises a first source and a first drain spaced from each other, and the first source extends towards the first drain and covers the first gate layer.

11. The electronic display device according to claim 10, wherein
a projection of the first source on the substrate has a first side close to the first drain;
a projection of the first gate layer on the substrate has a second side close to the first drain;
a projection of the first drain on the substrate has a third side close to the first source;
wherein the first side, the second side, and the third side are parallel to each other, and the first side is located between the second side and the third side.

12. The electronic display device according to claim 11, wherein a distance between the first side and the second side ranges from 0.5 μm to 10 μm.

13. The electronic display device according to claim 10, wherein the switching thin film transistor comprises:
a second active layer arranged on a same layer with the first active layer and spaced from the first active layer;
a second gate insulating layer arranged on a same layer with the first gate insulating layer and spaced from the first gate insulating layer;
a second gate layer arranged on a same layer with the first gate layer and spaced from the first gate layer; wherein the interlayer insulating layer extends and covers a surface of one side of the second gate layer away from the substrate; and
a second source/drain layer arranged on a same layer with the first source/drain layer and spaced from the first source/drain layer; wherein the second source/drain layer comprises a second source and a second drain spaced from each other.

14. The electronic display device according to claim 13, wherein each of the pixel units further comprises:
a scanning wiring unit arranged on a same layer with the second source/drain layer and arranged at intervals with the second source and the second drain respectively, wherein the scanning wiring unit is electrically connected to the second gate layer and arranged corresponding to the second gate layer.

15. The electronic display device according to claim 14, wherein
a projection of the scanning wiring unit on the substrate has a fourth side close to the second drain;
a projection of the second gate layer on the substrate has a fifth side close to the second drain;
a projection of the second drain on the substrate has a sixth side close to the second source;
wherein the fourth side, the fifth side, and the sixth side are parallel to each other, and the fourth side is located between the fifth side and the sixth side.

16. The electronic display device according to claim 15, wherein a distance between the fourth side and the fifth side ranges from 0.5 μm to 10 μm.

17. The electronic display device according to claim 14, wherein each of the pixel units further comprises:
a high-voltage access source arranged between the substrate and the buffer layer and electrically connected to the driving thin film transistor;
a low-voltage access source arranged on a same layer with the high-voltage access source and spaced from the high-voltage access source, wherein the low-voltage access source is electrically connected to the driving thin film transistor; and
a data wiring unit arranged on a same layer with the high-voltage access source and spaced from the high-voltage access source, wherein the data wiring unit is electrically connected to the switching thin film transistor.

18. The electronic display device according to claim 17, wherein each of the pixel units further comprises a first capacitor and an induction thin film transistor;
wherein the first gate layer is electrically connected to the second drain and the first capacitor, the first source is electrically connected to the low-voltage access source, and the first drain is electrically connected to the high-voltage access source;
wherein the second gate layer is electrically connected to the scanning wiring unit, the second source is electrically connected to the data wiring unit, and the second drain is electrically connected to the first capacitor; and
the induction thin film transistor comprises a third source electrically connected to the first capacitor.
